(19) United States
(12) Patent Application Publication
(10) Pub. No.: US 2021/0336110 A1
(43) Pub. Date: Oct. 28, 2021

(54) OPTOELECTRONIC SEMICONDUCTOR DEVICE HAVING A SUPPORT ELEMENT AND AN ELECTRIC CONTACT ELEMENT, AN OPTOELECTRONIC COMPONENT AND A METHOD OF PRODUCING THE OPTOELECTRONIC SEMICONDUCTOR DEVICE

(71) Applicant: OSRAM OLED GmbH, Regensburg (DE)

(72) Inventors: Christian Eichinger, Fußenberg, Gemeinde Wenzenbach (DE); Korbinian Perzlmaier, Regensburg (DE)

(21) Appl. No.: 17/273,459

(22) PCT Filed: Sep. 10, 2019
(86) PCT No.: PCT/EP2019/074135

§ 371 Date: Mar. 4, 2021

(30) Foreign Application Priority Data
Sep. 11, 2018 (DE) 10 2018 122 166.5

(51) Int. Cl. H01L 33/62; H01L 33/00; H01L 31/02; H01L 31/18

(52) U.S. Cl. CPC H01L 33/62; H01L 33/005; H01L 2933/0066; H01L 31/18; H01L 31/02005

(57) ABSTRACT

An optoelectronic semiconductor device includes a support element having a first main surface, an optoelectronic semiconductor chip which is arranged over the support element and adjacent to the first main surface, and an electrical contact element for contacting the optoelectronic semiconductor chip. The electric contact element is arranged in an opening formed in the first main surface of the support element.

### TECHNICAL FIELD

This disclosure relates to an optoelectronic semiconductor device having a support element and an electric contact element, an optoelectronic component and a method of producing the optoelectronic semiconductor device.

### BACKGROUND

For the purpose of producing optoelectronic semiconductor devices, optoelectronic semiconductor chips, for example, light-emitting or light-receiving semiconductor chips, are placed on suitable support elements and electrically contacted. Such support elements may, for example, have a horizontal main surface. Concepts are being sought by which an improved arrangement of the semiconductor chips on a support element may be achieved.

It could therefore be helpful to provide an improved optoelectronic semiconductor device and an improved method of producing an optoelectronic semiconductor device.

### SUMMARY

We provide an optoelectronic semiconductor device including a support element having a first main surface that is planar and free of topography; an optoelectronic semiconductor chip arranged over the support element and directly adjacent to the first main surface; and an electrical contact element adapted to contact the optoelectronic semiconductor chip, wherein the first main surface forms a closure of the support element, and the electrical contact element is arranged in an opening formed in the first main surface of the support element.

We also provide an optoelectronic component including a support element including a first main surface that is planar and free of topography; a first optoelectronic semiconductor chip arranged over the support element and directly adjacent to the first main surface; a second optoelectronic semiconductor chip arranged over the support element and directly adjacent to the first main surface; a first electrical contact element adapted to contact the first optoelectronic semiconductor chip; and a second electrical contact element adapted to contact the second optoelectronic semiconductor chip, wherein the first main surface forms a closure of the support element; and the electrical contact element is arranged in an opening formed in the first main surface of the support element.

We further provide a method of manufacturing an optoelectronic semiconductor device, including forming an opening in a first main surface of a support element, the first main surface being planar and free of topography, wherein the first main surface forms a closure of the support element; forming an electrical contact element in the opening; and arranging an optoelectronic semiconductor chip over the support element and directly adjacent to the first main surface, wherein the optoelectronic semiconductor chip is contacted via the electrical contact element.

### BRIEF DESCRIPTION OF THE DRAWINGS

FIG. 1A shows a vertical cross-sectional view of an example of an optoelectronic semiconductor device.

FIG. 1B shows a vertical cross-sectional view of an optoelectronic semiconductor device according to further examples.

FIGS. 2A and 2B each show vertical cross-sectional views of an optoelectronic semiconductor device according to further examples.

FIG. 2C shows a cross-sectional view of an optoelectronic component according to examples.

FIGS. 3A to 3E show cross-sectional views of a workpiece in the course of performing a method according to examples.

FIG. 4 outlines a method according to examples.

### LIST OF REFERENCES

10 optoelectronic semiconductor device
20 electromagnetic radiation
30 optoelectronic component
100 support element
101 first support layer
102 second support layer
103 third support layer
110 first main surface of the support element
111 second main surface of the support element
112 second main surface of the support layer stack
115 transparent substrate
120 first semiconductor layer
125 active region
130 second semiconductor layer
135 first contact region
136 second contact region
138 insulating material
140 conductive layer
142 circuit component
144 first control device
145 second control device
146 interconnection line
150 optoelectronic semiconductor chip
151 first main surface of the semiconductor chip
152 second main surface of the semiconductor chip
155 first optoelectronic semiconductor chip
156 second optoelectronic semiconductor chip
161 contact element
162 opening
163 via opening
164 interconnection element
165 first contact element
166 second contact element
167 insulating layer
170 interconnection structure

### DETAILED DESCRIPTION

Our optoelectronic semiconductor device comprises a support element comprising a first main surface, an optoelectronic semiconductor chip arranged above the support element and adjacent to the first main surface, and an electrical contact element that contacts the optoelectronic semiconductor chip. The electrical contact element is arranged in an opening formed in the first main surface of the support element.

The optoelectronic semiconductor chip may include contact regions arranged on a second main surface of the semiconductor chip arranged adjacent to the support element. A material of the support element may be selected from silicon, silicon oxide, silicon nitride, aluminum nitride, aluminum oxide, other semiconductor materials such as germanium or gallium arsenide, ceramic materials, glass, plastics, fiber-reinforced plastics, for example, glass-fiber reinforced plastics and printed circuit boards (PCB), and ceramic materials.

The first main surface of the support element may be planar and free of topography. For example, the first main surface may form a closure of the support element. The contact elements may be completely covered by the semiconductor chip.

The optoelectronic semiconductor device may furthermore comprise a connection structure extending from the first main surface of the support element to a second main upper surface of the support element.

The optoelectronic semiconductor device may also include a second support layer arranged beneath the support element. For example, circuit components may be arranged in the support layer or in the support element.

The optoelectronic semiconductor chip may emit or receive electromagnetic radiation.

Our optoelectronic component may comprise a support element comprising a first main surface, a first optoelectronic semiconductor chip arranged above the support element and adjacent to the first main surface, and a second optoelectronic semiconductor chip arranged above the support element and adjacent to the first main surface. The optoelectronic component may further comprise a first electrical contact element that contacts the first optoelectronic semiconductor chip and a second electrical contact element that contacts the second optoelectronic semiconductor chip. The first electrical contact element is arranged in a first opening formed in the first main surface of the support element, and the second electrical contact element is arranged in a second opening formed in the first main surface of the support element.

The optoelectronic component may further comprise a second support layer arranged beneath the support element.

For example, circuit components may be arranged in the support layer or in the support element. The first optoelectronic semiconductor chip may emit electromagnetic radiation, and the second optoelectronic semiconductor chip may receive electromagnetic radiation.

Our method of producing an optoelectronic semiconductor device comprises forming an opening in a first main surface of a support element, forming an electrical contact element in the opening, and arranging an optoelectronic semiconductor chip over the support element and adjacent to the first main surface. The optoelectronic semiconductor chip is contacted via the electrical contact element.

Forming the electrical contact element comprises depositing an electrically conductive material and subsequent planarizing a resulting surface, for example.

The accompanying drawings provide an understanding of examples of our devices, elements, components and methods. The drawings illustrate examples and, together with the description, serve for explanation thereof. Further examples and many of the intended advantages will become apparent directly from the following detailed description. The elements and structures shown in the drawings are not necessarily shown to scale relative to each other. Like reference numerals refer to like or corresponding elements and structures.

In the following detailed description, reference is made to the accompanying drawings, which form a part of the disclosure and in which specific examples are shown for purposes of illustration. In this context, directional terminology such as “top,” “bottom,” “front,” “back,” “over,” “on,” “in front,” “behind,” “leading,” “trailing” and the like refers to orientation of the figures just described. As the components of the examples may be positioned in different orientations, the directional terminology is used by way of explanation only and is in no way intended to be limiting.

The description of the examples is not limiting since there are also other examples, and structural or logical changes may be made without departing from the scope as defined by the appended claims. In particular, elements of the examples described below may be combined with elements from others of the examples described, unless the context indicates otherwise.

The term “vertical” as used in this description is intended to describe an orientation that is essentially perpendicular to the first surface of the semiconductor substrate or semiconductor body. The vertical direction may correspond, for example, to a direction of growth when layers are grown.

The terms “lateral” and “horizontal” as used in this description are intended to describe an orientation or alignment running essentially parallel to a first surface of a substrate or semiconductor body. This may be, for example, the surface of a wafer or a chip (die).

The horizontal direction may, for example, be in a plane perpendicular to a direction of growth when layers are grown.

To the extent used herein, the terms “have,” “include,” “comprise” and the like are open-ended terms that indicate the presence of the elements or features, but do not exclude the presence of further elements or features. The indefinite articles and the definite articles include both the plural and the singular, unless the context clearly indicates otherwise.

The semiconductor materials described herein may be based on semiconductor materials having a direct or an indirect band gap. Examples of semiconductor materials particularly suitable for generating electromagnetic radiation include, without limitation, nitride semiconductor compounds, by which, for example, ultraviolet, blue or longer-wave light may be generated such as GaN, InGaN, AlN, AlGaN, AlGaInN, phosphide semiconductor compounds by which, for example, green or longer-wave light may be generated such as GaAsP, AlGaInP, GaP, AlGaP, and other semiconductor materials such as AlGaAs, SiC, ZnSe, GaAs, ZnO, Ga₂O₃, diamond, hexagonal BN, and combinations of those materials. The stoichiometric ratio of the ternary compounds may vary. Other examples of semiconductor materials may include silicon, silicon germanium and germanium. The term “semiconductor” also includes organic semiconductor materials.

The term “electrically connected” means a low-ohmic electrical connection between the connected elements. The electrically connected elements need not necessarily be directly connected to one another. Further elements may be arranged between electrically connected elements. The term “electrically connected” also includes tunnel contacts between the connected elements.

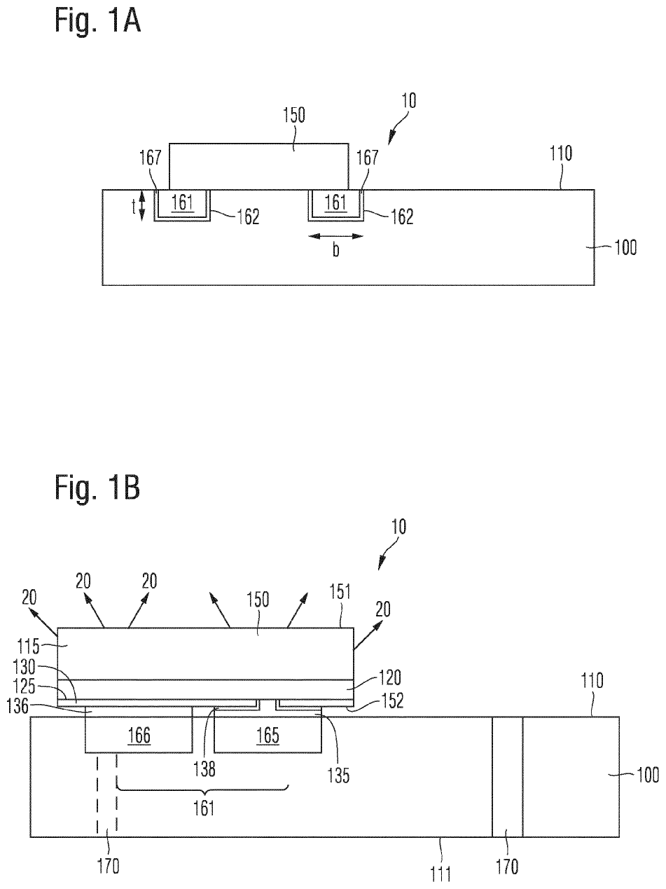

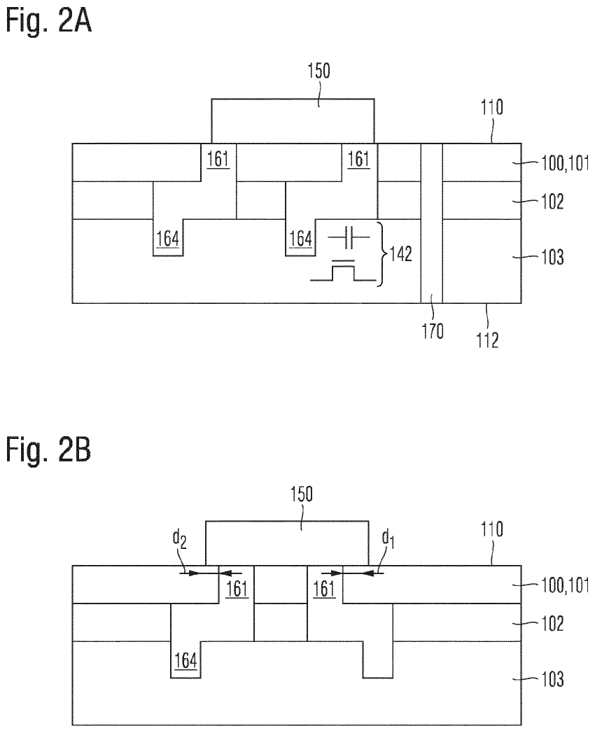

FIG. 1A shows a vertical cross-sectional view of an opto-electronic semiconductor device according to examples. The optoelectronic semiconductor device comprises a support element 100 comprising a first main surface 110 and an optoelectronic semiconductor chip 150 which is arranged directly adjacent to the first main surface 110 of the support element 100. The optoelectronic semiconductor chip 150 is arranged over the support element 100. The optoelectronic semiconductor device 10 further comprises an electrical contact element 161 that contacts the optoelectronic semiconductor chip 150. The electrical contact element 161 is formed in an opening 162 arranged in the first main surface 110 of the support element 100.

The support element 100 may, for example, be made of an insulating or semiconductor material. Examples include silicon, silicon oxide, silicon nitride, aluminum nitride, aluminum oxide, ceramic materials, and combinations of different materials. For example, the support element may be made of a base material and coated with one or more layers of one or more further materials. The first main surface 110 of the support element 100 is planar and free of topography, i.e., it has essentially no topography, that is to say, for example, steps, depressions or a surface roughness greater than 100 nm. “Essentially no topography” means that, for example, openings 162 may be formed in the first main surface 110, in which contact elements or other electrical interconnection structures may be received, the contact elements or electrical connection structures being largely flush with the first main surface 110. In other words, the first main surface of the support element is designed such that process steps for which a planar surface is important, for example, spin-on processes that apply a layer may be carried out. In particular, a planar surface allows for methods to be carried out that are sensitive to variations in height of the support element. The first main surface 110 forms a closure of the support element, for example.

The optoelectronic semiconductor chip may, for example, emit electromagnetic radiation. It may also be suitable to receive or absorb electromagnetic radiation. For example, the optoelectronic semiconductor chip 150 may be a light-emitting diode (LED). However, it may also be a sensor element. For example, the sensor element may detect electromagnetic radiation. The sensor element may, for example, detect electromagnetic radiation emitted by another optoelectronic semiconductor chip. It is also possible for the sensor element to detect ambient light, for example, the brightness of the environment. One example of a structure of the optoelectronic semiconductor chip 150 is described below with reference to FIG. 1B. The electrical contact element 161 may be formed from one or more electrically conductive materials. Examples of conductive materials include, among others, Au, Ni, Sn, Pt, Cu, Pd, Al, Ag, Cr, Mo, Rh, conductive oxides such as ITO (indium tin oxide) or zinc oxide, and others. The electrical contact element 161 may be composed of a plurality of layers. The contact element 161 may be electrically insulated from the support element by an additional insulating layer arranged between the contact element and the material 100 of the support element.

As an example, the opening 162 may extend into the support element 100 to a depth t of more than 10 nm, for example, more than 100 nm, for example, more than 500 nm, for example, 800 nm to 1.3 μm. The openings 162 may be of any cross-section. They may extend further in a plane perpendicular to the cross-sectional plane shown and may, for example, connect a plurality of optoelectronic semiconductor chips 160 to one another. A width b of the electrical contact elements 161 may, for example, be at least 300 nm. The width may also be at least 1 μm, for example. The width may be up to 300 μm, for example, less than 200 or less than 100 μm. As an example, the dimensions of the openings may be selected as a function of the electric currents at which the optoelectronic semiconductor chip 150 is operated.

Adjacent electrical contact elements 161 may be arranged at a suitable spacing to provide electrical insulation and avoid crosstalk.

By having the electrical contact element 161 arranged in an opening 162 formed in the first main surface 110 of the support element 100, the contact elements 161 do not create any topography on the support element 100. The support element 100 with the contact elements 161 applied may thus be processed without being impaired by any topography. In particular, methods of processing the support element for which a planar work surface is important due to their sensitivity to variations in height of the work surface, for example, spin-coating of resist materials may be carried out without impairment. Furthermore, the mechanical stability of the arrangement composed of optoelectronic semiconductor chip 150 and support element 100 is not impaired by the presence of protruding contact elements 161. In addition, the thermal connection of the optoelectronic semiconductor chip 150 to the support element 100 is improved, thereby improving heat dissipation and, thus, the efficiency of the optoelectronic device. Furthermore, contact levels and paths may be further miniaturized. In addition, the mechanical stability of the arrangement is improved.

Depending on the nature of the support element 100, i.e., in particular whether it is insulating or not, an insulating layer 167 may additionally be provided that insulates each of the contact elements 161 from the support element 100.

FIG. 1B shows a vertical cross-sectional view of an opto-electronic semiconductor device according to examples. As shown in FIG. 1B, the optoelectronic semiconductor device 10 comprises the elements shown in FIG. 1A. In addition, an electrical interconnection structure 170 is also shown that may, for example, represent a through silicon via (TSV) structure and may be suitable to connect elements on the first main surface 110 of the optoelectronic semiconductor device with components on the second main surface 111 of the support element 100. The electrical interconnection structure 170 may also be connected to the first or the second contact element 165, 166, as further indicated in FIG. 1B.

The optoelectronic semiconductor chip 150 may be an LED, for example. As an example, a first semiconductor layer 120 of a first conductivity type, for example, n-type may be arranged over a transparent substrate 115, for example, a sapphire substrate. The transparent substrate may also be omitted. A second semiconductor layer 130 of a second conductivity type, for example, p-type may be arranged over the first semiconductor layer 120. An active region 125 may be arranged between the first semiconductor layer 120 and the second semiconductor layer 130. The active region 125 may, for example, have a pn junction, a double heterostructure, a single quantum well structure (SQW, single quantum well) or a multiple quantum well structure (MQW, multi quantum well) that generates radiation. The term “quantum well structure” does not imply any particular meaning here with regard to the dimensionality of the quantization. Therefore it includes, among other things, quantum wells, quantum wires and quantum dots as well as any combination of these structures.

A first contact region 135 is connected to the first semiconductor layer 120 in an electrically conductive manner. A second contact region 136 is connected to the second semiconductor layer 130 in an electrically conductive manner. For example, the first contact region and the second contact region may each be arranged on the side of the second main surface 152 of the semiconductor chip 150. The semiconductor chip 150 thus represents a flip chip. The first contact region 135 may be electrically insulated from the second semiconductor layer 130 by an insulating material 138. Electromagnetic radiation 20 emitted by the optoelectronic semiconductor chip 150 may be emitted via the first main surface 151, for example. Furthermore, the electromagnetic radiation 20 may also be emitted via side surfaces of the transparent substrate 115. If the optoelectronic semiconductor chip 150 is suitable for receiving electromagnetic radiation, this radiation may be incident via the first main surface 151. The semiconductor chip 150 is arranged such that the first contact region 135 is connected in an electrically conductive manner to the first contact element 165. Furthermore, the second contact region 136 is connected to the second contact element 166 in an electrically conductive manner. In the arrangement shown in FIG. 1B, the contact elements 161, 165, 166 are placed such that they are completely covered by the optoelectronic semiconductor chip 150. As a result, radiation incident from outside from one side of the first main surface 110 of the support may not be reflected by the contact elements 161, 165, 166.

The first contact region 135 may have a different lateral dimension from the first contact element 165. In the same manner, the second contact region 136 may have a different lateral dimension from the second contact element 166. Furthermore, the first contact region 135 and the first contact element 165 are not required to be aligned flush with one another. Nor are the second contact region 136 and the second contact element 166 required to be aligned flush with one another.

In general, the optoelectronic semiconductor chip may comprise insulating and/or metallic layers. As an example, they may be created by applying or depositing a corresponding layer. The layers may be applied before a semiconductor wafer is singulated into semiconductor chips.

The semiconductor chip 150 may be directly adjacent to a first main surface 110 of the support element 100. This does not rule out the possibility for the optoelectronic semiconductor chip 150 to not touch the first main surface 110 of the support element. Rather, there may be a thin air gap between the semiconductor chip and the first main surface of the support element. For example, an insulating or other material that at least partially surrounds the semiconductor chip 150 and has been applied, for example, after the singulation of a semiconductor wafer into individual semiconductor chips, may be absent from the area between the semiconductor chip 150 and the support element 100. As an example, an insulating or other material that covers side surfaces of the optoelectronic semiconductor chip may be absent from the area between the semiconductor chip 150 and the support element 100.

Several support layers may be stacked on top of one another such that, as a result, a structure comprising several levels may be provided, for example, for a more complex contact architecture or for a functional division of the individual levels.

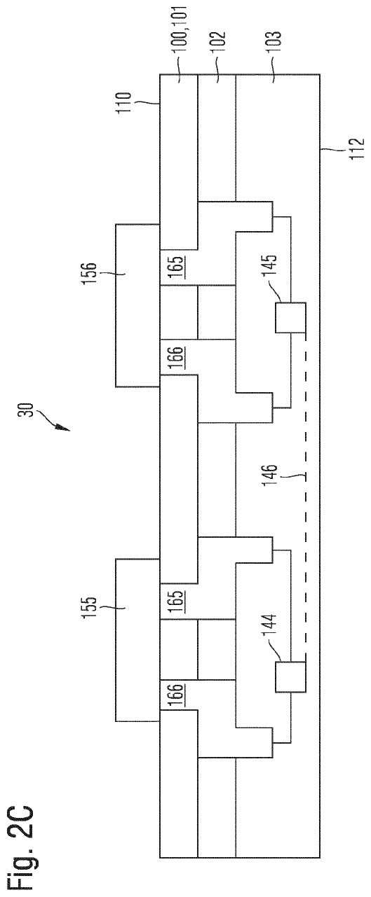

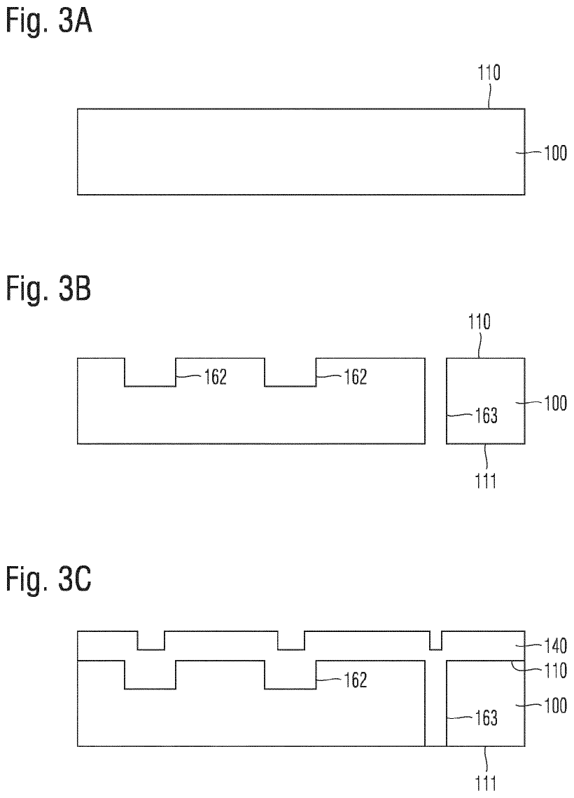

FIG. 2A shows a vertical cross-sectional view of an opto-electronic semiconductor device according to further examples. The semiconductor device illustrated in FIG. 2A comprises a support element 100 (hereinafter referred to as first support layer 101) arranged over a second support layer 102. The second support layer 102 in turn is arranged over a third support layer 103. Each of these support layers may be composed of identical or different materials, respectively. As an example, the third support layer 103 or any other layer may be a silicon substrate having circuit components 142 arranged therein. Circuit components 142 may include, for example, active or passive semiconductor devices such as transistors, resistor elements, switching elements, capacitors, and others. The circuit components 142 arranged in the third support layer 103 may, for example, be connected to the contact elements 161 via suitable connecting elements 164. The circuit components 142 may be connected to the optoelectronic semiconductor chip 150 via the contact elements 161. However, it is also possible for electrical circuit components to be arranged in each of the support layers or in a support layer other than the third support layer. Furthermore, it is possible that additional support layers are present. Furthermore, a connection element (not shown) may be provided in one of the support layers, for example, the second support layer 102 to establish electrical contact between interconnection elements 164 and further components. For example, such an interconnection element 164 may respectively connect the contact elements 161 that are connected to adjacent optoelectronic semiconductor chips. Furthermore, a contact element may each be provided in the first support layer 101 to electrically connect the optoelectronic semiconductor chips. For example, one of the layers may be insulating, while others of the layers are semiconducting or conductive. Examples of materials for the insulating support layer include, for example, silicon oxide, silicon nitride, aluminum oxide, tantalum oxide, niobium oxide, silicon oxynitride, aluminum nitride, and other insulating materials that may be used for multilayer structures. These may, for example, have been deposited by CVD or PVD processes. Further examples are ceramics, glasses such as spin-on glasses. The materials mentioned may have different stoichiometric ratios. An interconnection structure 170 may be provided to connect regions on the first main surface 110 of the first support layer to components on the rear side of the third support layer, for example. The interconnection structure 170 may, for example, also connect interconnection elements 164 or contact elements 161 within the support layers or with the second main surface 112 of the support layer stack.

FIG. 2B shows a schematic cross-sectional view of an optoelectronic semiconductor device according to further examples. In contrast to the semiconductor device shown in FIG. 2A, the contact elements 161 and parts of the interconnection elements 164 are in this example arranged such that they are shaded and covered by the optoelectronic semiconductor chip 150. More precisely, there is a distance d1 specifying a length by which the right-hand side edge of the semiconductor chip 150 protrudes beyond the right-hand contact element 161. In a corresponding manner, the left-hand side edge of the optoelectronic semiconductor chip 150 projects beyond the left contact element 161 by the distance d2. In this manner, reflections of light incident from one side of the first main surface 110 of the first support layer 101 may effectively be avoided at the contact elements 161.

FIG. 2C shows a vertical cross-sectional view of an optoelectronic component. The optoelectronic component may contain a single support element 100 or different support layers, for example, a first, a second and a third support layer 101, 102, 103 or more. In particular, the optoelectronic component 30 comprises a first optoelectronic semiconductor chip 155 and a second optoelectronic semiconductor chip 156. These may each be connected via a first contact element 165 and a second contact element 166 to further elements which are arranged, for example, in a support element or a support layer or over the support element. As an example, the first contact element and the second contact element of the first optoelectronic semiconductor chip may be connected to a first control device 144. The first contact element and the second contact element 165, 166 of the second optoelectronic semiconductor chip may, for example, be connected to a second control device 145.

As an example, the first control device and/or the second control device 144, 145 may contain circuit components that may, for example, be formed in the third support layer 103 or in another support layer. The first and second control devices 144, 145 may be connected to one another via an interconnection line 146, for example. The first and the second control device may, for example, be contacted by the second main surface 112 of the support layer stack. For example, further circuit components may be arranged in any one of the support layers. Alternatively or additionally, driver circuits and processing devices may furthermore be arranged in any of the support layers.

The first optoelectronic semiconductor chip may emit electromagnetic radiation. The second optoelectronic semiconductor chip 156 may include an optical sensor element, for example, that receives radiation emitted by the first optoelectronic semiconductor chip, which radiation has been reflected by an object, for example. The corresponding signals may be processed in the first and second control devices. As an example, the optoelectronic component shown in FIG. 2C includes an iris scanner or some other device by which reflected light is suitably processed. The second optoelectronic semiconductor chip 156 may also detect ambient light or other electromagnetic radiation and may, for example, control the first semiconductor chip 155 taking into account the detection result.

The optoelectronic component may also comprise a matrix arrangement or any arrangement of light-emitting or light-receiving devices, whereby a large-area lighting device or a display device may be provided. For this purpose, elements of a driver circuit for the individual optoelectronic semiconductor chips may be arranged in the support element or in one of the support layers, for example. Furthermore, signals received by the optoelectronic semiconductor chip may be processed by a signal processing device, the components of which are arranged in the support element or in one of the support layers.

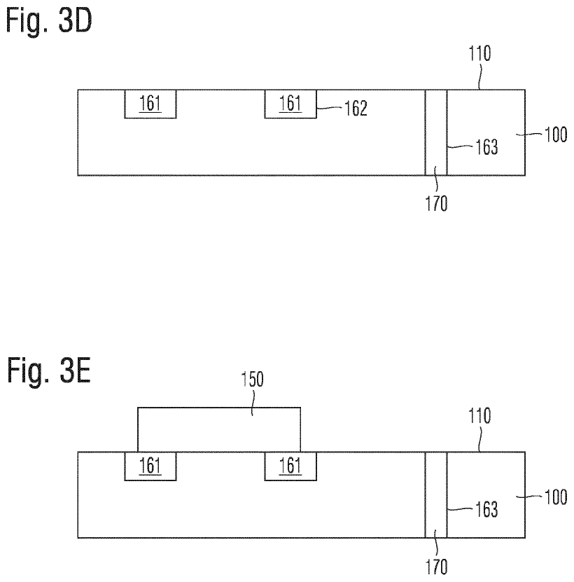

FIGS. 3A to 3E illustrate cross-sectional views of a workpiece during production of the opto-electronic semiconductor device described.

FIG. 3A shows a cross-sectional view of a support element 100 comprising a first main surface 110. In particular, the first main surface 110 may be planar, i.e., initially, no depressions are formed in the substrate 100.

Then, as shown in FIG. 3B, openings 162 and optionally via openings 163 are formed. The via opening 163 may, for example, extend from the first main surface 110 of the support element 100 to the second main surface 111 of the support element. The openings 162 are formed in the region of the first main surface 110. They may be trench-like, i.e., extend in a direction perpendicular to the illustrated cross-sectional plane. They may essentially not extend in a direction perpendicular to the cross-sectional plane. As an example, the openings 162, 163 may be defined by a lithographic process. As an example, exposed areas are defined in a photoresist material in which the first main surface 110 of the support element 100 is not covered by a photoresist material. An etching process is then carried out to etch the substrate. Examples of etching processes include, for example, dry etching processes such as plasma etching. Next, a conductive layer is applied over the first main surface 110 of the support element 100 as shown in FIG. 3C. This may be carried out, for example, by methods such as electroplating, vapor deposition or sputtering. The patterned photoresist material may be removed before or after the metallization layer is applied.

Then, as shown in FIG. 3D, a planarization process is carried out so that a planar surface is obtained. This may be carried out, for example, by a CMP (chemical-mechanical polishing) process and/or a polishing process or by an etch-back process. As a result, the structure of the support element 100 obtained in FIG. 3D is obtained. The support element shown in FIG. 3D may be processed further in a simple manner without any issues arising from protruding contact elements 161 or protruding interconnection structures 170. As an example, processes sensitive to height variations such as spin coating of thin layers consisting, for example, of a resist material, may be carried out.

Subsequently, a solder material containing indium, for example, may be formed at locations where the semiconductor chips are to be applied to the support element. Alternatively, a dielectric lacquer or an anisotropically conductive adhesive may be applied.

In a next step, as shown in FIG. 3E, optoelectronic semiconductor chips 150 are placed on the first main surface 110 so that they are electrically connected to the contact elements 161.

For the purpose of producing a multi-level architecture comprising several support layers stacked on top of one another, the support layers may, for example, be processed individually and then stacked on top of one another. One support layer may first be processed. A further support layer is then applied onto this support layer and processed accordingly. This sequence is continued until the support layer stack is complete and the contact element in the uppermost support layer has been formed. Then the semiconductor chip is applied.

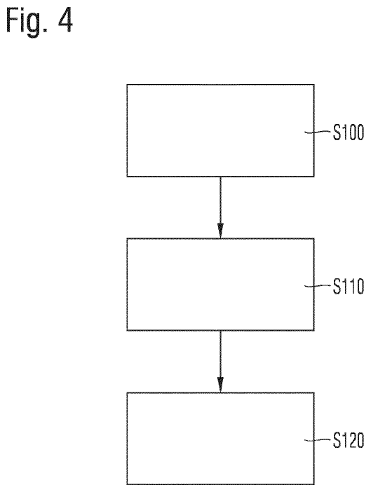

FIG. 4 outlines a method according to examples.

A method of producing an optoelectronic semiconductor device comprises forming (S100) an opening in a first main surface of a support element, forming (S110) an electrical contact element in the opening, and arranging (S120) an optoelectronic semiconductor chip over the support element and adjacent to the first major surface. The optoelectronic semiconductor chip is contacted via the electrical contact element. Forming (S110) the electrical contact element may, for example, include depositing an electrically conductive material and subsequent planarizing a resulting surface.

Although specific examples have been illustrated and described herein, those skilled in the art will recognize that the specific examples shown and described may be replaced by a multiplicity of alternative and/or equivalent configurations without departing from the scope of this disclosure. This disclosure is intended to cover any adaptations or variations of the specific examples discussed herein. Therefore, the disclosure is to be limited by the appended claims and their equivalents only.

This disclosure claims priority of DE 10 2018 122 166.5, the subject matter of which is incorporated herein by reference.

1-19. (canceled)

20. An optoelectronic semiconductor device comprising:
a support element having a first main surface that is planar and free of topography;
an optoelectronic semiconductor chip arranged over the support element and directly adjacent to the first main surface; and
an electrical contact element adapted to contact the optoelectronic semiconductor chip,
wherein the first main surface forms a closure of the support element, and
the electrical contact element is arranged in an opening formed in the first main surface of the support element.

21. The optoelectronic semiconductor device according to claim 20, wherein the optoelectronic semiconductor chip comprises a first and a second contact region each of which is arranged on a second main surface of the semiconductor chip arranged adjacent to the support element.

22. The optoelectronic semiconductor device according to claim 20, wherein a material of the support element is selected from silicon, silicon oxide, silicon nitride, aluminum nitride, aluminum oxide, germanium, gallium arsenide, ceramic materials, glass, plastics, fiber-reinforced plastics, glass fiber reinforced plastics and printed circuit boards.

23. The optoelectronic semiconductor device according to claim 20, wherein the contact element is completely covered by the semiconductor chip.

24. The optoelectronic semiconductor device according to claim 20, further comprising an interconnection structure extending from the first main surface of the support element to a second main surface of the support element.

25. The optoelectronic semiconductor device according to claim 20, further comprising an interconnection structure electrically connected to the electrical contact element.

26. The optoelectronic semiconductor device according to claim 25, wherein the interconnection structure extends to a side of the support element facing away from the first main surface of the support element.

27. The optoelectronic semiconductor device according to claim 20, further comprising a support layer arranged beneath the support element.

28. The optoelectronic semiconductor device according to claim 20, further comprising a circuit component arranged in the support layer or in the support element.

29. The optoelectronic semiconductor device according to claim 20, wherein the optoelectronic semiconductor chip is configured to emit electromagnetic radiation.

30. The optoelectronic semiconductor device according to claim 20, wherein the optoelectronic semiconductor chip is configured to receive electromagnetic radiation.

31. An optoelectronic component comprising:
a support element comprising a first main surface that is planar and free of topography;
a first optoelectronic semiconductor chip arranged over the support element and directly adjacent to the first main surface;
a second optoelectronic semiconductor chip arranged over the support element and directly adjacent to the first main surface;
a first electrical contact element adapted to contact the first optoelectronic semiconductor chip; and
a second electrical contact element adapted to contact the second optoelectronic semiconductor chip,
wherein the first main surface forms a closure of the support element; and
the electrical contact element is arranged in an opening formed in the first main surface of the support element.

32. The optoelectronic component according to claim 31, further comprising a support layer arranged beneath the support element.

33. The optoelectronic component according to claim 31, wherein the circuit components are arranged in the support layer or in the support element.

34. The optoelectronic component according to claim 31, wherein the first optoelectronic semiconductor chip is configured to emit electromagnetic radiation and the second optoelectronic semiconductor chip is configured to receive electromagnetic radiation.

35. A method of manufacturing an optoelectronic semiconductor device, comprising:
forming an opening in a first main surface of a support element, the first main surface being planar and free of topography, wherein the first main surface forms a closure of the support element;
forming an electrical contact element in the opening; and
arranging an optoelectronic semiconductor chip over the support element and directly adjacent to the first main surface,
wherein the optoelectronic semiconductor chip is contacted via the electrical contact element.

36. The method of claim 35, wherein forming the electrical contact element comprises depositing an electrically conductive material and subsequently planarizing a resulting surface.
